(19) United States
(12) Patent Application Publication
(10) Pub. No.: US 2009/0020807 A1
(43) Pub. Date: Jan. 22, 2009

(54) SEMICONDUCTOR DEVICE AND METHOD FOR FABRICATING THE SAME

(75) Inventor: Je Yong YOON, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/176,738

(22) Filed: Jul. 21, 2008

(30) Foreign Application Priority Data
Jul. 19, 2007 (KR) 10-2007-0072162

(51) Int. Cl. H01L 21/336; H01L 29/78

(52) U.S. Cl. 257/327; 438/282; 257/E21.428; 257/E29.27

(57) ABSTRACT

Disclosed are a semiconductor device and a method for fabrication of the same. The fabrication method may include selectively forming an oxide layer pattern on a semiconductor substrate, forming an insulation layer pattern on the same substrate to cover edge portions of the oxide layer pattern, etching the oxide layer pattern and the substrate to form a recess as well as first and second oxide layer patterns corresponding to the edge portions of the oxide layer pattern, forming a third oxide layer pattern on the substrate in the recess to produce a gate insulation layer comprising the first, second, and third oxide layer patterns, and forming a gate pattern in the recess. The fabricated semiconductor device minimizes occurrence of current leakage such as gate induction drain leakage, among other things, thereby improving transistor performance.

### CROSS-REFERENCE TO RELATED APPLICATION

This application claims the benefit of Korean Patent Application No. 10-2007-0072162, filed on 19 Jul. 2007, which is hereby incorporated by reference in its entirety.

### BACKGROUND

1. Field of the Invention

Embodiments of the present invention relate to a semiconductor device and a method for fabrication thereof and, more particularly, to a semiconductor device with a recess gate structure and a method for fabrication of the same.

2. Discussion of the Related Art

A MOS transistor includes a gate, a drain region and a source region. Due to the concurrent increase in complexity and/or integration of semiconductor devices there is high demand for a reduction in MOS transistor dimensions. However, if source and drain junction depth dimensions of a MOS transistor are decreased too much, a source and drain depletion region can penetrate into a channel region, resulting in a reduced effective channel length. The reduced effective channel length, in turn, causes a reduction in threshold voltage, thereby causing a “short channel effect” and leading to a loss of gate control functions of a MOS transistor. In addition, a decrease in channel length may result in problems such as current leakage, including Gate Induced Drain Leakage (GIDL).

### SUMMARY OF SOME EXAMPLE EMBODIMENTS

In general, example embodiments of the invention relate to a semiconductor device, e.g., a transistor, and a method for fabrication of the same that substantially minimize or avoid current leakage problems, such as GIDL, and/or other problems that can occur when reducing transistor dimensions.

According to a first embodiment, a method for fabrication of a semiconductor device comprises selectively forming an oxide layer pattern on a semiconductor substrate; forming an insulation layer pattern on the same substrate to cover edge portions of the oxide layer pattern; etching the oxide layer pattern and the substrate to form a recess as well as first and second oxide layer patterns corresponding to the edge portions of the oxide layer pattern; forming a third oxide layer pattern on the substrate in the recess to produce a gate insulation layer comprising the first, second, and third oxide layer patterns; and forming a gate pattern in the recess.

According to a second embodiment, a semiconductor device comprises a gate pattern formed in a recess below a surface of the semiconductor substrate; a source region formed in the substrate at one side of the gate pattern and a drain region formed in the substrate at the other side of the gate; and a gate insulation layer including a first oxide layer pattern formed at a first edge of the recess to separate the gate pattern from the drain region and to reduce overlap between the gate pattern and the drain region, a second oxide layer pattern formed at a second edge of the recess to separate the gate pattern from the source region, and a third oxide layer pattern formed around an inner wall of the recess.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

Additional features will be set forth in the description which follows, and in part will be obvious from the description, or may be learned by the practice of the teachings herein. Features of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

The accompanying drawings, which are included to provide a further understanding of example embodiments of the invention and are incorporated in and constitute a part of this application, illustrate the example embodiments and together with the description serve to explain particular features of the example embodiments. In the drawings:

FIG. 1 to FIG. 8 are cross-sectional views illustrating stages of a method for fabrication of a semiconductor device according to an exemplary embodiment of the present invention.

### DETAILED DESCRIPTION OF SOME EXAMPLE EMBODIMENTS

In the following detailed description of a semiconductor package and a method for fabrication thereof, reference is made to the accompanying drawings that show, by way of illustration, specific embodiments of the invention. These embodiments are described in sufficient detail to enable those skilled in the art to practice the invention. Other embodiments may be utilized and structural, logical, and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

In the following detailed description it will be understood that “first,” “second,” and like terms are used to distinguish among individual semiconductor members without limitation thereof. Accordingly, when a semiconductor member is referred to as “first,” “second,” and the like, it is clearly understood that the semiconductor can comprise at least two such members and, optionally, can include replaceable members. Moreover, for convenience of explanation, dimensions of different elements have been illustrated in exaggerated scale and the scale shown in the drawings may be different from that of practical dimensions of the elements. Furthermore, elements illustrated in the drawings are not necessarily included in every embodiment of the invention, nor are un-illustrated elements particularly restricted. Thus, various non-essential elements may be added or deleted, as deemed appropriate by one of ordinary skill in the art. It will further be understood that when a layer (film), a region, a pad, a pattern and/or a structure are referred to as being “on/above/over/upper (on top of)” or “down/below/under/lower (on bottom of)” another substrate, layer (film), region, pad and/or pattern, they can directly contact the other substrate, layer (film), region, pad or pattern, and/or may have one or more intervening layers (films), regions, pads, patterns or structures present therebetween.

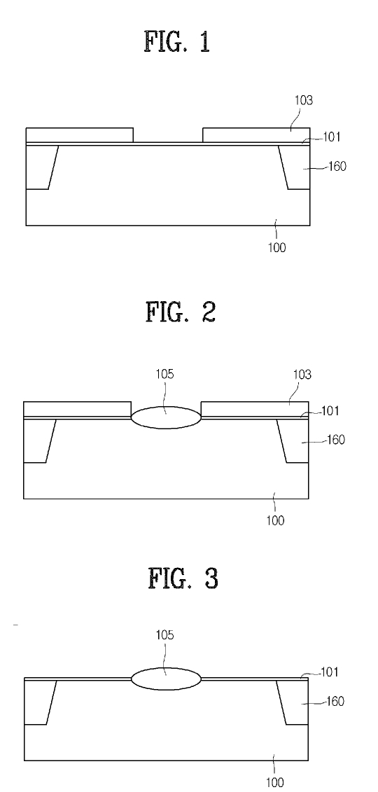

FIGS. 1 to 8 are cross-sectional views illustrating procedures for fabrication of a semiconductor device according to an exemplary embodiment.

As illustrated in FIG. 1, a device isolation layer pattern 160 may be formed on a semiconductor substrate 100 to define an active region of the substrate. The device isolation layer pattern 160 may include, for instance, a shallow trench isolation pattern.

A buffer oxide layer 101 may be formed on an upper surface of the substrate 100 with the device isolation layer pattern 160. The buffer oxide layer 101 may include, e.g., an oxide layer formed by thermal oxidation.

An additional silicon nitride layer (not shown) may be formed on the buffer oxide layer 101.

A first insulation layer pattern 103 may be formed on the buffer oxide layer 101. The first insulation layer pattern 103 may include tetraethylorthosilicate (TEOS).

As illustrated in FIG. 2, a portion of the substrate 100 exposed by the first insulation layer pattern 103 may be subjected to oxidation. However, if a silicon nitride layer has been formed on the buffer oxide layer 101, the silicon nitride layer may first undergo a selective etching process using the first insulation layer pattern 103 as a mask to expose a region of the substrate 100 where an oxide layer pattern will be formed.

The oxide layer may selectively be grown on the substrate 100 in a region where the substrate 100 is exposed by the first insulation layer pattern 103, thereby forming an oxide layer pattern 105.

As illustrated in FIG. 3, the first insulation pattern 103 may then be removed to expose the buffer oxide layer 101 and the oxide layer pattern 105.

The oxide layer pattern 105 may be formed so as to protrude upwardly relative to the buffer oxide layer 101. Thus, the oxide layer pattern 105 may be thicker than the buffer oxide layer 101.

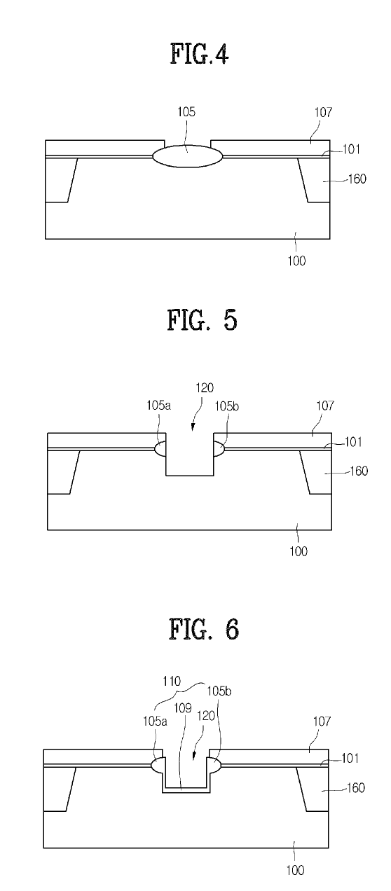

As illustrated in FIG. 4, a second insulation layer pattern 107 may be formed on the substrate 100. The second insulation layer pattern 107 may be formed using a nitride film.

The second insulation layer pattern 107 may completely cover the buffer oxide layer 101 while partially covering the oxide layer pattern 105. In particular, the second insulation layer pattern 107 may cover outer edge portions of the oxide layer pattern 105. The edge portions may each have a certain minimum, maximum, or predetermined length. Accordingly, the oxide layer pattern 105 may be partially exposed by the second insulation layer pattern 107.

The second insulation layer pattern 107 may have an opening having a width substantially equal to the width of a gate pattern to be subsequently formed.

The oxide layer pattern 105 and the substrate 100 may then be etched, using the second insulation layer pattern 107 as a mask, to form a recess 120.

The recess 120 may be formed through the oxide layer pattern 105 so that only the opposite edge portions of the oxide layer pattern 105 remain. The edge portions may correspond to a first oxide layer pattern 105a and a second oxide layer pattern 105b, respectively, each having substantially the same thicknes (i.e., a first thickness).

While the second insulation layer pattern 107 remains in place, the substrate 100 may be oxidized, e.g., by thermal oxidation, to form a third oxide layer pattern 109 having a second thickness in the recess 120, as illustrated in FIG. 6.

In particular the third oxide layer pattern 109 may be formed when a portion of the substrate 100 exposed in the recess 120 is oxidized. The third oxide layer pattern 109 may have a second thickness that is thinner than the first thickness of each of the first and the second oxide patterns 105a and 105b.

The first oxide layer pattern 105a, the second oxide layer pattern 105b, and the third oxide layer pattern 109 together form a gate insulation layer 110. Thus, the gate insulation layer 110 has different thicknesses at different positions thereof, such that the gate insulation layer 110 is thicker at the edges than at the center thereof.

As disclosed above, since the gate insulation layer 110 has an increased thickness at each edge thereof, it is possible to reduce an electric field strength between the gate and the source/drain, thereby minimizing GIDL.

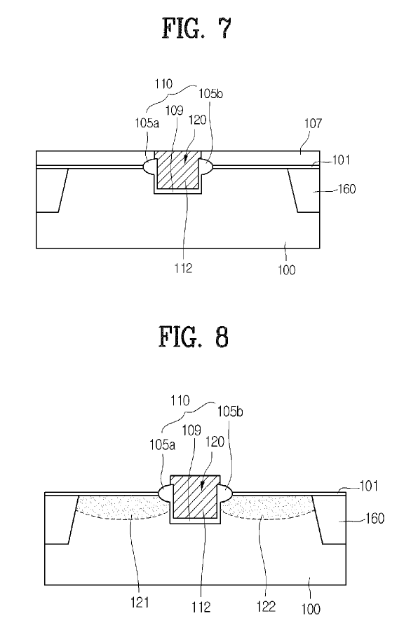

As illustrated in FIG. 7, a gate pattern 112 embedded in the recess 120 may be formed by depositing polysilicon on the second insulation pattern 107 to form a polysilicon layer and polishing the polysilicon layer by a Chemical Mechanical Polishing CMP process. Alternatively, the gate pattern 112 may be formed by patterning the polysilicon layer through a mask process.

In order to reduce contact resistance, a metal silicide layer may additionally be formed on the gate pattern 112. The metal silicide layer may comprise at least one material selected from a group comprising tungsten silicide, tantalum silicide, and molybdenum silicide.

As illustrated in FIG. 8, the second insulation pattern 107 may then be removed.

The gate pattern 112 may protrude upwardly relative to the gate layer 110 by a certain minimum, maximum, or predetermined length.

A gate capping layer, which may be formed using a silicon nitride film, may additionally be formed on the substrate 100 with the gate pattern 112.

A source region 121 and a drain region 122 may be formed by implantation of high concentration impurity ions to the active region of the substrate 100 where the gate pattern 112 is not formed.

At each upwardly protruding side wall of the gate pattern 112, a gate spacer may be formed, e.g., above the first and second oxide layer patterns 105a and 105b. The gate spacer may comprise at least one material selected from a group comprising a silicon oxide film, a silicon nitride film, and a silicon oxide nitride film.

In a transistor, which has the recess gate structure fabricated as described above, it is possible to decrease the overlap between the gate region and the drain region because of the gate layer 110, thereby reducing GIDL. Thus, the above described semiconductor device and method for fabrication thereof effectively minimize occurrence of current leakage such as GIDL, among other things, and, thus, improve performance of a transistor.

Although a few embodiments of the present invention have been described above, it will be apparent to those skilled in the art that the present invention covers variations and/or modifications not illustrated in the above description, without departing from the sprit or scope of the invention. For example, a variety of variations and modifications can be made to technical elements described in the embodiments. Such variations and modifications are construed to come within the scope of the invention defined in the appended claims.

What is claimed is:

1. A method for fabrication of a semiconductor device comprising:
selectively forming an oxide layer pattern on a semiconductor substrate;
forming an insulation layer pattern on the substrate to cover edge portions of the oxide layer pattern;
etching the oxide layer pattern and the substrate to form a recess as well as first and second oxide layer patterns corresponding to the edge portions of the oxide layer pattern;
forming a third oxide layer pattern on the substrate in the recess to form a gate insulation layer comprising the first, second, and third oxide layer patterns; and
forming a gate pattern in the recess.

2. The method according to claim 1, wherein the method further includes:
removing the insulation layer pattern after forming the gate pattern; and
implanting impurity ions into the substrate at both sides of the gate pattern to form a source region and a drain region.

3. The method according to claim 1, wherein the step of selectively forming the oxide layer pattern on the substrate includes:
forming a buffer oxide layer on an upper surface of the substrate;
forming a mask pattern on the buffer oxide layer to expose a portion where the oxide layer pattern is formed;
oxidizing the exposed portion of the buffer oxide layer, such that the oxide layer pattern is thicker than the buffer oxide layer; and
removing the mask pattern.

4. The method according to claim 3, wherein the method further includes forming a silicon nitride layer between the buffer oxide layer and the mask pattern.

5. The method according to claim 4, wherein the silicon nitride layer is selectively etched using the mask pattern to expose a portion where the oxide layer pattern is formed.

6. The method according to claim 3, wherein the buffer oxide layer is formed by thermal oxidation.

7. The method according to claim 3, wherein the mask pattern comprises tetraethylorthosilicate (TEOS).

8. The method according to claim 1, wherein the insulation layer pattern comprises a nitride film.

9. The method according to claim 1, wherein the third oxide layer has a thickness smaller than a thickness of each of the first oxide layer pattern and the second oxide layer pattern.

10. The method according to claim 1, wherein the first oxide layer pattern and the second oxide layer pattern have substantially the same width.

11. The method according to claim 1, wherein the third oxide layer pattern is formed by thermal oxidation.

12. A semiconductor device comprising:
a gate pattern formed in a recess below a surface of a semiconductor substrate;
a source region formed in the substrate at one side of the gate pattern and a drain region formed in the substrate at the other side of the gate pattern; and
a gate insulation layer including a first oxide layer pattern formed at a first edge of the recess to separate the gate pattern from the drain region and to reduce overlap between the gate pattern and the drain region, a second oxide layer pattern formed at a second edge of the recess to separate the gate pattern from the source region, and a third oxide layer pattern formed around an inner wall of the recess.

13. The semiconductor device according to claim 12, wherein the first oxide layer pattern and the second oxide layer pattern each have a thickness larger than that of the third oxide pattern layer.

14. The semiconductor device according to claim 12, wherein the first oxide layer pattern and the second oxide layer pattern have substantially the same size.

15. The semiconductor device according to claim 12, wherein the gate pattern protrudes upwardly from the gate insulation layer.
